(19) United States
(12) Patent Application Publication
(10) Pub. No.: US 2002/0096767 A1
(43) Pub. Date: Jul. 25, 2002

(54) Cavity down ball grid array package with EMI shielding and reduced thermal resistance

(76) Inventors: Kevin J. Cote, Margarita, CA (US); Doug A. Hawks, Escondido, CA (US)

Correspondence Address: BROBECK, PHLEGER & HARRISON LLP, 12390 EL CAMINO REAL, SAN DIEGO, CA, 92130, US

(21) Appl. No.: 09/774,066

(22) Filed: Jan. 25, 2001

(51) Int. Cl. H01L 21/44; H01L 23/48; H01L 23/52; H01L 29/40

(52) U.S. Cl. 257/738; 438/613

(57) ABSTRACT

In a cavity down ball grid array integrated circuit package, a metal lid is clamped and soldered to a ground ring of the top tier of the substrate of the package. During the BGA surface mount process, the back side of the metal lid is soldered to the board. This method provides grounded EMI shielding for the integrated circuit's die and bond wires, and an additional thermal path through the lid to ground, improving EMI and thermal conductivity of the package. A thermally conductive mold compound or a thermal pad can be used as the filler material between the lid and the die. The lid can be flat or contoured to the die and the die's surrounding area. Contouring of the lid reduces the distance between the lid and the die, further improving thermal conductivity of the package.

### BACKGROUND OF THE INVENTION

1. Field of the Invention

The present invention relates to integrated circuit packaging, and, more particularly, to cavity down ball grid array integrated circuit packaging with improved electromagnetic interference shielding and thermal characteristics.

2. Background

Integrated circuits (“ICs”) are formed on semiconductor dies, most commonly made of silicon. For handling convenience, ease of use, and reliability, the dies are often encapsulated in a protective mold material. The mold material can be ceramic, plastic, or resin. To provide an electrical interface to an IC's signal, power, and ground lines, the IC package includes an electrical connector extending from the integrated circuit to the outside of the package.

One IC package type known to those skilled in the art of IC package design is a Pin Grid Array (“PGA”) package. In a PGA, a plurality of pins extend from the undersurface of the package to the outside. The pins provide an electrical interface between the IC package and external circuitry. They are arranged in multiple rows and columns. Hence, the “grid array” designation. A cutout of a PGA package is illustrated in FIG. 1. In that figure, pins 120, arranged in a grid array, protrude from the bottom portion 110 of the PGA package 100.

A Ball Grid Array (“BGA”) package is similar to a PGA package. The difference between the two is, that in a BGA package, conductive spheres replace the pins used in a PGA package. The conductive spheres are often solder balls. A cutout view of a conventional BGA package is depicted in FIG. 2. A bottom view of the same BGA package is shown in FIG. 3. As can be seen from these two figures, conductive spheres 220 populate underside 210 of the BGA package 200.

Use of the conductive spheres as an electrical interface between the package and the external circuitry permits surface mounting of the BGA package. The package is placed on a printed circuit board (“PCB”), with the conductive spheres positioned on top of the PCB's pads. For every conductive sphere there is a corresponding pad on the board. The spheres are then soldered to the pads.

One fundamental advantage of grid array-based IC packages, such as BGAs, is that they allow high density interconnects between the ICs and the printed circuit boards on which the ICs are eventually installed. The high density interconnects, i.e., high lead densities and counts, result from using all or a portion of the area of a surface of the IC for multiple rows and columns of the electrical interface. In comparison, the well known dual-in-line (“DIP”) and quad flat pack (“QFP”) packages use only edges of the IC packages for the interconnect. The increased area utilization in grid array packages allows chip designers to place more leads in a given package size.

High lead counts of BGA packages are needed to support high and constantly increasing IC circuit densities. High circuit densities tend to aggravate the problems of electromagnetic interference (“EMI”), electromagnetic susceptibility, and heat dissipation.

EMI means incidental electromagnetic radiation emitted by an electronic device in the course of its operation. Electromagnetic susceptibility is the susceptibility of a device to EMI generated by other devices. Unless indicated otherwise, we use the “EMI” moniker to refer generically to electromagnetic interference and susceptibility.

To address the heat dissipation and EMI problems, a “cavity down” BGA package has been developed. FIG. 4 is a cross-section of such a package. As illustrated, die 410 is attached to an electrically and thermally conducting plate 420 by die attach adhesive layer 430. Conducting plate 420 is known as a “heat spreader” or a “heat slug.” Wire bonds 440 connect signals from die 410 to substrate 450, which is also attached to the heat spreader 420.

As is known to those skilled in the art, a substrate is essentially a signal redistribution means. Signals from the semiconductor die connect to pads on various layers of the substrate through wire bonds 440. From the various layers of the substrate the signals are brought out to the conductive spheres on the connector surface of the substrate by holes plated with a conductive material, such as copper. The holes are known as “vias.” Each via brings to the substrate's surface one electrical connection, such as an interface signal, ground, or power line. IC substrates are often made from multi-layered printed circuit board.

Encapsulate 460 fills the cavity of the BGA package, protecting die 410 and wire bonds 440. The heat spreader 420 evenly distributes the heat generated by die 410, thereby lowering peak temperatures and increasing heat flow into the PCB where the package is installed. Additionally, if the heat spreader is exposed to an airflow, it may dissipate some of the heat into the airflow.

Although the cavity down BGA package improves EMI and thermal characteristics (thermal conductivity and heat flow) of a standard BGA package, still better characteristics are demanded by modern IC designers.

One attempt to improve EMI shielding of BGA packages is taught by U.S. Pat. No. 5,294,826, issued to Marcantonio et al. (“the '826 patent”). The method of the '826 patent embeds EMI shielding in the substrate of the package. Thus, the package of the '826 patent provides shielding only in one plane of the package. It does not surround the wire bonds and the die of the IC package with grounded shielding material.

A later, related attempt to improve both EMI shielding and thermal conductivity of BGA packages is found in U.S. Pat. No. 5,796,170 to Marcantonio (“the '170 patent”). The method described in the '170 patent uses peripheral conductive spheres of the BGA package, and conductive spheres surrounding critical signal leads (lines), as grounds shorted to the heat slug of the package. This method reduces the number of available lines for signal inputs and outputs because all the spheres on the periphery of the IC, and many additional spheres surrounding the critical signals, must be grounded. Package size and cost therefore increase.

U.S. Pat. No. 5,986,340 to Mostafazadeh et al. (“the '340 patent”) describes a BGA package where the semiconductor die mounted on a substrate is completely surrounded with a massive metal heat sink. The heat sink is thicker than the combined thickness of the substrate and the die. It requires metal tie bars to connect the substrate to the heat sink. This arrangement increases the total area and thickness of the package.

Furthermore, it appears that the relatively thin tie bars, through which die-generated heat must travel, reduce heat conductivity from the die to the heat conducting plate (heat spreader) of the package. It also appears that because of the large area of the heat sink, solder may flow from underneath the heat sink onto adjacent areas of the substrate. This would cause short circuits between the conducting spheres located there. Finally, the extra thickness of the heat sink may interfere with the use of the capillary tool during wire bonding operation, because the capillary tool requires a minimum clearance distance around it. Thus, the total area of the package may have to be increased to provide the required clearance for the capillary tool.

A need therefore exists for a BGA package design that has improved EMI shielding and thermal characteristics.

### SUMMARY OF THE INVENTION

The present invention provides a cavity down ball grid array integrated circuit package with a semiconductor die mounted on a heat spreader. A substrate with an opening is attached to the heat spreader so that the semiconductor die is located in the substrate's opening. Bond wires bring signals from the pads on the surface of the die to the substrate. The substrate's vias connect the signals to a plurality of conducting spheres that reside on the surface of the substrate opposite the surface attached to the heat spreader. A ground ring is formed on one of the substrate's layers. It substantially surrounds the die and the wires connecting the die to the substrate. An electrically conductive EMI shielding cap or lid covers the die and the bond wires in the substrate's opening. The electrically conductive cap is physically and electrically attached to the ground ring. The cap is therefore grounded through the ring. An electrically conductive enclosure, i.e., a Faraday cage, is thus formed around the die and the bond wires.

To provide direct grounding for the electrically conductive cap and an additional thermal path for the heat generated in the die, the outside of the electrically conductive cap is preferably attached (e.g., soldered) to the end user's board where the integrated circuit package is installed. This allows the heat generated in the die of the package to find a second path to the end user's board through the filler of the cavity (if any) and the electrically conductive cap, especially if the cap is soldered to the end user's board. Thus, thermal conductivity of the package may be increased.

Using a thermally conductive pad inside the cavity formed under the cap, instead of the more common mold compounds, further improves thermal conductivity of the BGA package. Additional improvement in thermal conductivity is achieved by contouring the inside surface of the cap (i.e., the surface facing the die) to match closely the surface of the die, the die attach area, and the portions of the substrate with the wire bonds. Contouring decreases the distance between the die and the electrically conductive cap, permitting more of the die-generated heat to travel to the cap and into the end user's board.

### BRIEF DESCRIPTION OF THE DRAWING

FIG. 1, described above, is a perspective view of a cutout of a conventional pin grid array integrated circuit package.

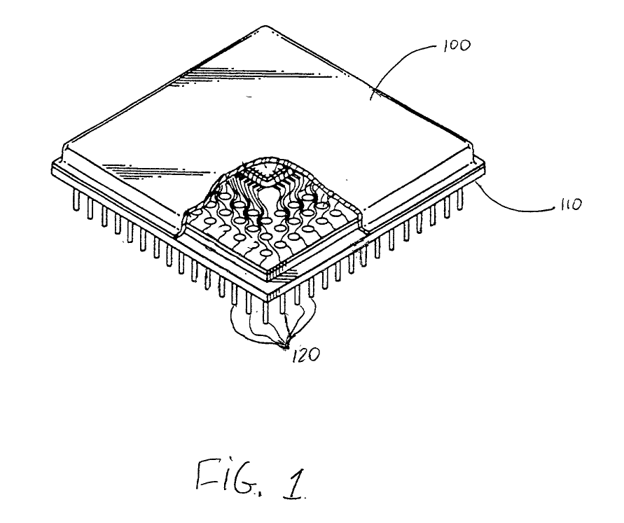

FIG. 2, described above, is a perspective view of a cutout of a conventional ball grid array integrated circuit package.

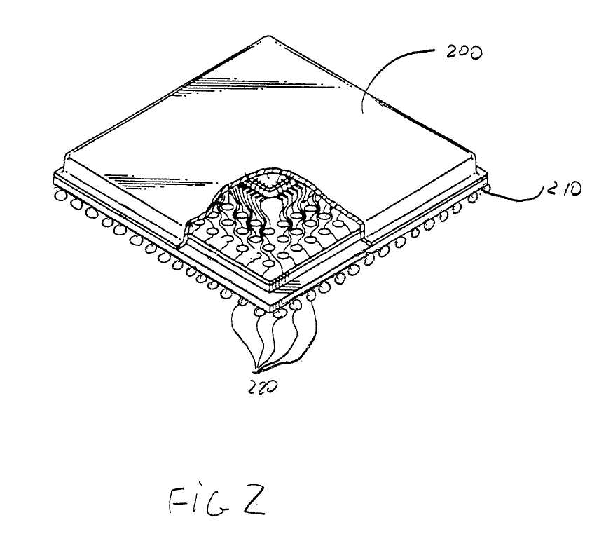

FIG. 3, described above, is a schematic bottom view of a conventional ball grid array integrated circuit package.

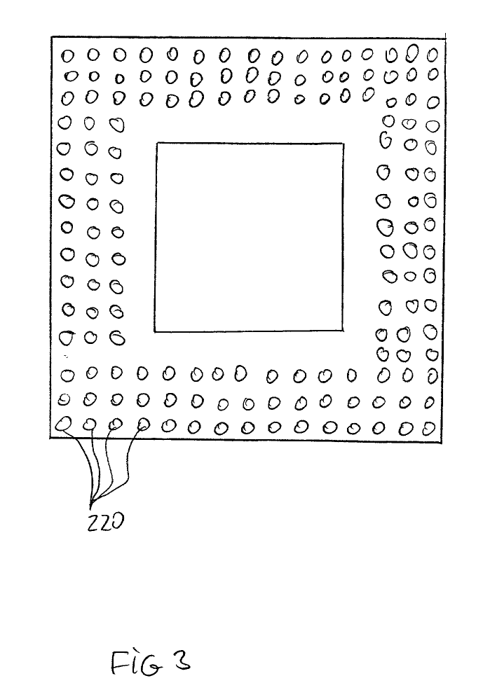

FIG. 4, described above, is a cross-sectional view of a conventional cavity down ball grid array integrated circuit package.

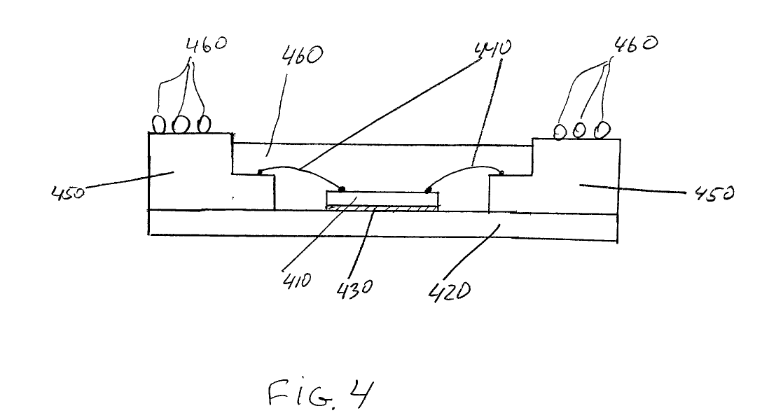

FIG. 5 illustrates a cross-section of an improved cavity down BGA package according to the present invention.

FIG. 6 is a side elevation view of a portion of a contoured lid according to the present invention.

FIG. 7 illustrates installation of an improved cavity down BGA package on an end user's board with the conductive cap soldered to the board.

### DETAILED DESCRIPTION

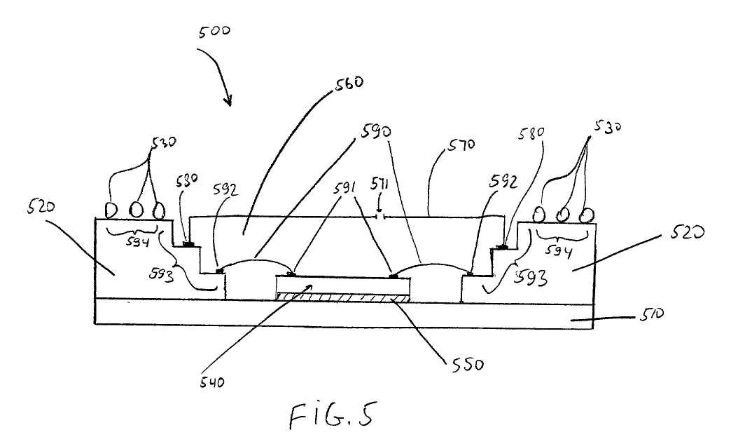

FIG. 5 shows a first embodiment of a cavity down BGA 500 with an EMI shielding cap. Semiconductor (e.g., silicon) die 540 is attached to heat spreader 510 with die attach adhesive layer 550. Any of the well known epoxies may be used as the die attach layer, e.g., epoxy resins, bismaleimide resins, or cyanate ester resins. The heat spreader 510 may be constructed of a metal that is a good heat conductor, such as copper. As is known to those skilled in the art, a good heat conductor is usually also a good electrical conductor.

Substrate 520 is also attached to the heat spreader 510, and generally surrounds die 540, so that die 540 is located within an opening of substrate 520. The substrate is a signal redistribution layer that connects electrical signals from the semiconductor die to the package's external connector, described below. The substrate can be a multi-layered PCB with vias.

Wire bonds 590 connect electrical signals from die bonding pads 591 to inner bonding pads 592 of wire bond connect area 593 on substrate 520. The wire bonds may be made of suitable conducting metal, such as copper or gold. The inner bonding pads may be gold vapor deposited on the die. Vias inside the substrate 520 connect the inner bonding pads 592 to conductive spheres 530 situated on connector area 594. The vias and the bonding pads of the substrate are made of a conductive material, for example, copper.

For illustration, two tiers of the substrate 520 are visible on the portion of the substrate adjacent to the die 540. Inner bonding pads 591 lie on the lower tier. Ground ring 580 is a conductive surface formed on the top tier. There can be other tiers corresponding to the various layers of the printed circuit board of the substrate, and the top tier, where the ground ring is located, may coincide with the top surface of the substrate.

The ground ring 580 substantially surrounds the die 540. It is preferably shaped as a geometric circle or a square, facilitating fabrication and installation of the conductive cap 570. The conductive cap is physically and electrically attached to the ring, e.g., by soldering.

Encapsulate (filler) 560 occupies the volume under the conductive cap. The encapsulate may be a sealing resin, e.g., a thermosetting epoxy synthetic resin. In one embodiment, the encapsulate is a hardened mold compound introduced into the volume through aperture 571 in the cap 570. Although one aperture 571 is illustrated, several apertures 571 may be provided for this purpose.

The semiconductor die 540 and the wire bonds 590 are located within a volume substantially surrounded by the ground ring 580, heat spreader 510, and the cap 570. These components are preferably good electrical conductors. Therefore, they form a Faraday cage that improves the EMI performance of the IC package by shielding the die 540 and the bond wires 590 from external electromagnetic interference. Conversely, the Faraday cage blocks electromagnetic fields generated by the die 540 and the bond wires 590 from radiating outside of the IC package.

(By Faraday cage we mean an enclosure, possibly with openings, made of conductive materials. A Faraday cage shields the volume inside the enclosure from external EMI, and contains electromagnetic fields generated inside the enclosure.)

Thermal conductivity of the inventive shielded cavity down BGA is higher than thermal conductivity of the prior art cavity down BGAs. The increase in thermal conductivity results from heat flow from the die, through the encapsulate, to the electrically conductive cap, and then into the end user's board where the BGA is eventually installed. But conventional mold compounds, e.g., sealing resins that are used for IC package encapsulation, are poor heat conductors. To improve thermal performance of the IC package, the encapsulate may be a dielectric material with high thermal conductivity. Preferably, the dielectric material has heat conductivity of at least 2.0W/m-K.

Instead of a mold compound, a dielectric thermal pad made of a heat conducting material can be used. Thermagon T-pli 200 series thermal pad, available from THERMAGON, Inc., 4707 Detroit Avenue Cleveland, Ohio 44102, tel. no. 216-939-2300, is suitable for such use. After the die attach and wire bonding operations during manufacture of the IC package, the thermal pad with single-sided adhesive is placed on the top surface of the die. The conductive cap is then clamped to the substrate to ensure solid contact with the substrate and compression of the pad. (Compression is desirable because it increases thermal conductivity of the thermal pad, and because it ensures that the pad will fill the volume more fully, displacing air pockets. Preferably, compression exceeds 25%, i.e., the thickness of the compressed pad is less than 75% of the thickness of the uncompressed pad.) The cap is then physically and electrically attached to the ground ring, for example, by soldering.

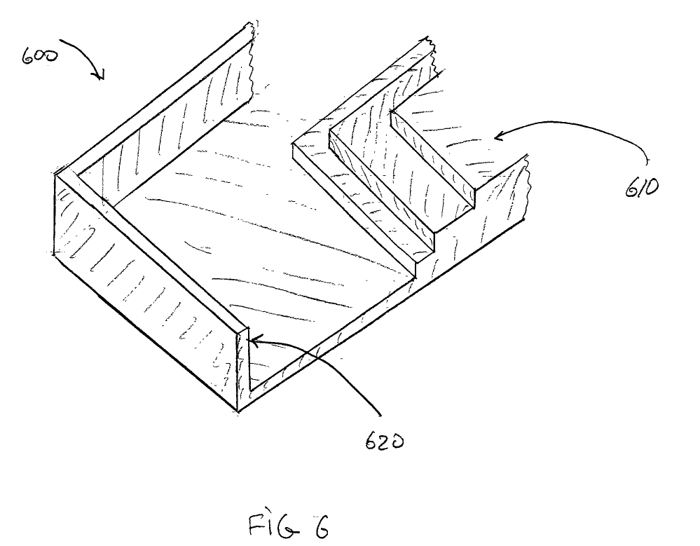

Another way to improve heat conductivity of the package is by contouring the conductive cap to the surfaces of the die, of the die attach area of the heat spreader, and of a portion of the substrate. Contouring decreases average distance between the heat producing portions of the package, mainly the die, and the electrically (and thermally) conductive cap. Contouring may be used in conjunction with thermally conductive encapsulate or thermal pad discussed above. A quarter section of a contoured cap 600 is shown in FIG. 6. Numeral 610 designates the contoured portion of the cap, while numeral 620 designates the skirt of the cap. Although the illustrated skirt 620 is square, implying a square ground “ring,” as described above, the skirt can be implemented as a true ring or as another geometric shape.

In operation, when the IC package is installed on end user's board, the conductive cap of the package may be attached to a pad of the end user's board. This is done, for example, by soldering. Soldering of the conductive cap may be performed at the same time as soldering of the electrical interface of the IC package, i.e., of the conductive spheres, to the end user's board. To facilitate the optional arrangement, the height of the conductive cap should be approximately the same as the height of the conductive spheres of the IC package.

Preferably, the pad of the end user's board, to which the conductive cap is soldered, is grounded. This arrangement provides a good ground to the Faraday cage of the IC package, further improving EMI characteristics of the package. Moreover, in practice, grounding the cap to the end user's board is likely to improve heat flow from the conductive cap into the board because good thermal connections are generally also good electrical connections.

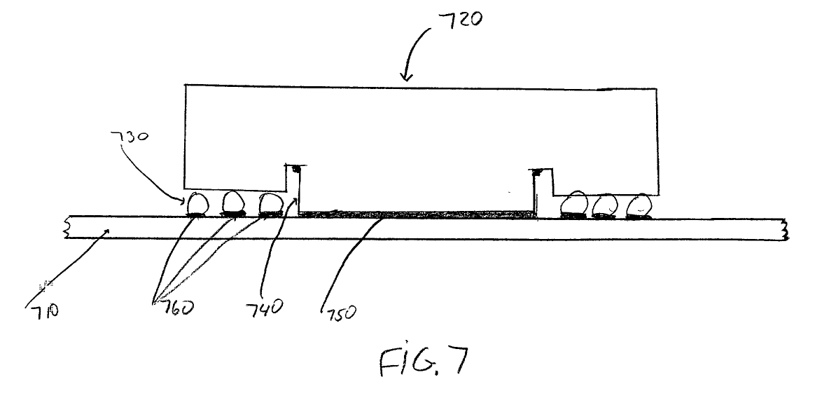

Such arrangement is illustrated in FIG. 7. The cavity down shielded BGA IC package 720 is installed on end user's PCB 710. Conductive spheres 730 and conductive cap 740 are in contact with, and soldered to, pads of PCB 710. Solder joints between the PCB pads and conductive spheres 730 are designated with numeral 760; solder joint between conductive cap 740 and the PCB pad is designated with numeral 750.

From the above description of the invention it is manifest that various equivalents can be used to implement the concepts of the present invention without departing from its scope. Moreover, while the invention has been described with specific reference to certain embodiments, a person of ordinary skills in the art would recognize that changes can be made in form and detail without departing from the spirit and the scope of the invention. The described embodiments are to be considered in all respects as illustrative and not restrictive. It should also be understood that the invention is not limited to the particular embodiments described herein, but is capable of many equivalents, rearrangements, modifications, and substitutions without departing from the scope of the invention.

What is claimed is:

1. A cavity down grid array integrated circuit package comprising:
a heat spreader;
a semiconductor die attached to the heat spreader;
a substrate having portions defining an opening and a wire bond connect area, the wire bond connect area including a ground ring, the substrate being attached to the heat spreader so that the die is located within the opening;
a plurality of wire bonds connecting the die to the substrate;
an electrical connector for connecting the package to external circuitry; and
an electrically conductive cap connected to the ground ring so that the die and the wires are between the cap and the heat spreader.

2. A cavity down ball grid array integrated circuit package comprising:
a heat spreader;
a semiconductor die having a plurality of die bonding pads;
a die attach layer attaching the die to the heat spreader;
a substrate having a bottom side, a top side, a wire bond connect area with a plurality of inner bonding pads and a ground ring thereon, portions defining an opening, a connector area on the top side, and vias connecting the inner bonding pads to the connector area, the substrate being attached to the heat spreader so that the die is located within the opening;
a plurality of wires connecting the die bonding pads to the inner bonding pads;
a plurality of conductive spheres attached to the connector area, the spheres being in contact with the vias; and
an electrically conductive cap connected to the ground ring so that the die is between the cap and the heat spreader.

3. A package according to claim 2, further comprising encapsulate material substantially filling space between the die and the cap.

4. A package according to claim 3, wherein the cap is thermally conductive, the heat spreader is thermally and electrically conductive, and the substrate is a multi-layered printed circuit board.

5. A package according to claim 3, wherein the encapsulate material is a dielectric having heat conductivity of at least 2.0 W/m-K.

6. A package according to claim 5, wherein the encapsulate material is a thermal tape.

7. A package according to claim 6, wherein the thermal tape is a single sided adhesive thermal tape.

8. A package according to claim 7, wherein the single sided adhesive thermal tape is compressed between the cap and the die.

9. A package according to claim 7, wherein the single sided adhesive thermal tape is compressed at least twenty-five percent.

10. A package according to claim 5, wherein the cap is contoured to reduce distance between the cap and the die.

11. A package according to claim 3, wherein the cap comprises portions defining an aperture, and the encapsulate is a mold compound injected through the aperture.

12. A cavity down grid array integrated circuit package comprising:
a means for heat spreading;
a means for signal redistribution having a tiered portion defining an opening, the tiered portion including a ground ring means, the signal redistribution layer being attached to the heat spreading means;
a semiconductor die located in the opening of the means for signal redistribution;
means for electrically connecting the semiconductor die to the means for signal redistribution;
means for electrically connecting the package to external circuitry; and
means for attaching the semiconductor die to the heat spreading means;
an EMI shielding means attached to the ground ring means.

13. A package according to claim 12, further comprising encapsulate means substantially filling space between the semiconductor die and the EMI shielding means.

14. A package according to claim 13, wherein the encapsulate means has thermal conductivity of at least 2.0 W/m-K.

15. A package according to claim 14, wherein the encapsulate means is a thermal pad compressed at least twenty-five percent.

16. A method for improving EMI properties of a package manufactured according to claim 12, the method comprising the step of soldering the means for EMI shielding to a ground of an external board.

17. A method for improving EMI shielding for a cavity down IC package comprising the following steps:
providing an electrically conductive cap;
positioning the cap around the die of the package; and
attaching the cap to a ground in the substrate of the package.

18. A method for improving EMI shielding for a cavity down IC package according to claim 17, further comprising the step of providing a ground connection between the cap and an end user's board.
